(19) United States
(12) Patent Application Publication
(10) Pub. No.: US 2026/0276224 A1
(43) Pub. Date: Sep. 17, 2026

(54) SYSTEM FOR CURB CAP SIZE SELECTION IN AN EXHAUST FAN

(71) Applicant: Greenheck Fan Corporation, Schofield, WI (US)

(72) Inventors: Eric P. Steinbach, Wausau, WI (US); Scott S. Kurszewski, Wittenberg, WI (US); Matt R. Koehler, Mosinee, WI (US); Luke S. Hilleshiem, Kronenwetter, WI (US); David R. Mayer, Kronenwetter, WI (US)

(21) Appl. No.: 19/671,797

(22) Filed: May 8, 2026

Related U.S. Application Data
(62) Division of application No. 18/159,059, filed on Jan. 24, 2023, now abandoned.

(51) Int. Cl. F24F 7/02; G06F 3/048; G06F 30/17; G06Q 30/0601

(52) U.S. Cl. CPC F24F 7/025; G06F 3/048; G06F 30/17; G06Q 30/0621

(57) ABSTRACT

A system for manufacturing a fan with a curb cap having a sidewall for coupling to a roof curb. The system comprises a data collection device having a display configured to present first, second, and third curb cap options with first, second and third curb cap sidewall dimensions which are numerically different from one another and configured to interface with different first, second, and third roof curbs. The system further comprises a user input device in communication with the data collection device and operable by a user to select either the first, second, or third curb cap option, a data storage device configured to store data relating to the selected curb cap option, and an assembly subsystem configured to receive the data and at least partially manufacture the fan with the curb cap having a sidewall at least partially defining the sidewall dimension of the selected curb cap option.

### CROSS-REFERENCE TO RELATED APPLICATION

This application is a divisional of co-pending U.S. Patent Application No. 18/159,059 filed Jan. 24, 2023, the entire contents of which are incorporated herein by reference.

### FIELD OF THE DISCLOSURE

The present disclosure relates to a system for manufacturing an exhaust fan, and more particularly to system for manufacturing a fan with either a first curb cap size or a second curb cap size.

### BACKGROUND OF THE INVENTION

Fans such as roof mounted exhaust fans remove air from internal spaces within buildings. Depending on the function of the space, time of day, occupancy, building codes, intake, and other factors, such spaces may require more or less air turnover. Roof mounted exhaust fans must be controlled and operated to meet these requirements. Conventional roof mounted exhaust fans are manufactured with curb caps having a limited number of predetermined and preselected sizes based on the size of a motor and/or an impeller of the exhaust fan.

### SUMMARY OF THE INVENTION

The present disclosure provides a system for manufacturing a fan with a curb cap having a sidewall for coupling to a roof curb, the system including: a data collection device having a display configured to present a first curb cap option defining a first curb cap sidewall dimension configured to interface with a first roof curb, a second curb cap option defining a second curb cap sidewall dimension configured to interface with a second roof curb, and a third curb cap option defining a third curb cap sidewall dimension configured to interface with a third roof curb, wherein the first curb cap sidewall dimension, the second curb cap sidewall dimension, and the third curb cap sidewall dimension are numerically different from one another, and wherein the first roof curb, the second roof curb, and the third roof curb are different from one another; a user input device in communication with the data collection device, the user input device operable by a user to select either the first curb cap option, the second curb cap option, or the third curb cap option; a data storage device configured to store data relating to the selected curb cap option; and an assembly subsystem configured to receive the data from the data storage device and at least partially manufacture the fan with the curb cap having a sidewall at least partially defining the sidewall dimension of the selected curb cap option.

The present disclosure provides a method of manufacturing a fan with a curb cap having sidewalls configured to interface with a roof curb, the method including: gathering user input data regarding airflow requirements of the fan; selecting a motor and an impeller configured to meet the airflow requirements; storing data regarding the selected motor and the selected impeller in a data storage device; presenting to a user a first curb cap option defining a first curb cap sidewall dimension configured to interface with a first roof curb, a second curb cap option defining a second curb cap sidewall dimension configured to interface with a second roof curb, and a third curb cap option defining a third curb cap sidewall dimension configured to interface with a third roof curb; gathering user input data regarding a user selected curb cap representing either the first curb cap option, the second curb cap option, or the third curb cap option; and at least partially manufacturing with an assembly subsystem the fan with the motor, the impeller, and the curb cap having a sidewall with the sidewall dimension of the selected curb cap option.

The present disclosure provides a fan including: a motor, and an impeller rotatably coupled to the motor, wherein the motor is configured to be coupled to any one curb cap selected from a group of three or more curb caps, each of the curb caps of the group having a curb cap sidewall dimension differing from the curb cap sidewall dimension of the other curb caps of the group by a predetermined numerical increment.

Other features and aspects of the disclosure will become apparent by consideration of the following detailed description and accompanying drawings.

### BRIEF DESCRIPTION OF THE DRAWINGS

FIG. 1 is a perspective view of an exhaust fan.

FIG. 2 is an exploded view of the exhaust fan of FIG. 1.

FIG. 3 is a top view of the exhaust fan of FIG. 1 with a hood thereof removed.

FIG. 4 is a cross-sectional view of the exhaust fan of FIG. 1 taken along section line 4—4 in FIG. 3.

FIG. 5 is an enlarged cross-sectional view of the exhaust fan of FIG. 1 taken along section line 5—5 in FIG. 4.

FIG. 6 is a block diagram illustrating a system for curb cap size selection and manufacturing of the exhaust fan of FIG. 1.

FIG. 7 illustrates a display of a data collection device.

FIG. 8 is an engaged illustration of a curb size display window.

FIG. 9 is a flow diagram illustrating a method of manufacturing the exhaust fan, the method including a curb cap size selection process.

Before any embodiments of the disclosure are explained in detail, it is to be understood that the disclosure is not limited in its application to the details of construction and the arrangement of components set forth in the following description or illustrated in the following drawings. The disclosure is capable of supporting other embodiments and of being practiced or of being carried out in various ways. Also, it is to be understood that the phraseology and terminology used herein is for the purpose of description and should not be regarded as limiting.

### DETAILED DESCRIPTION

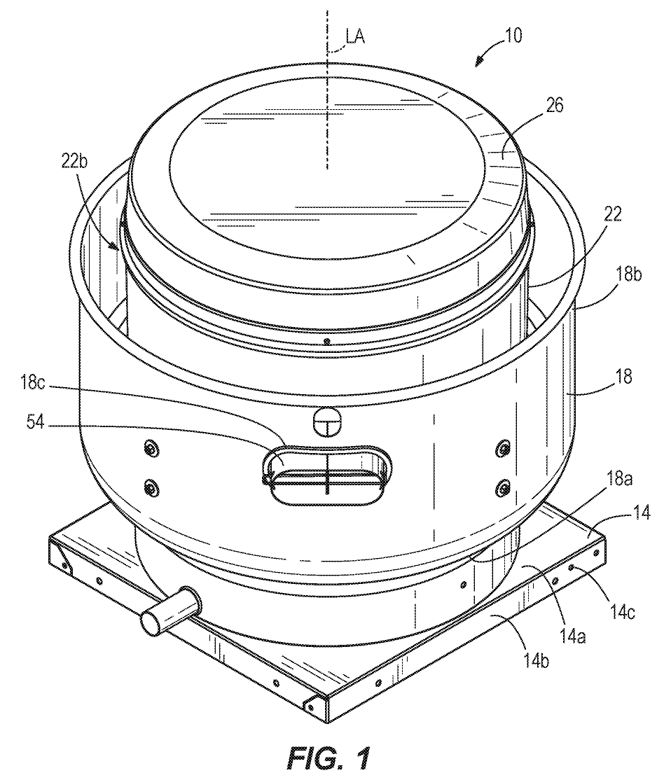

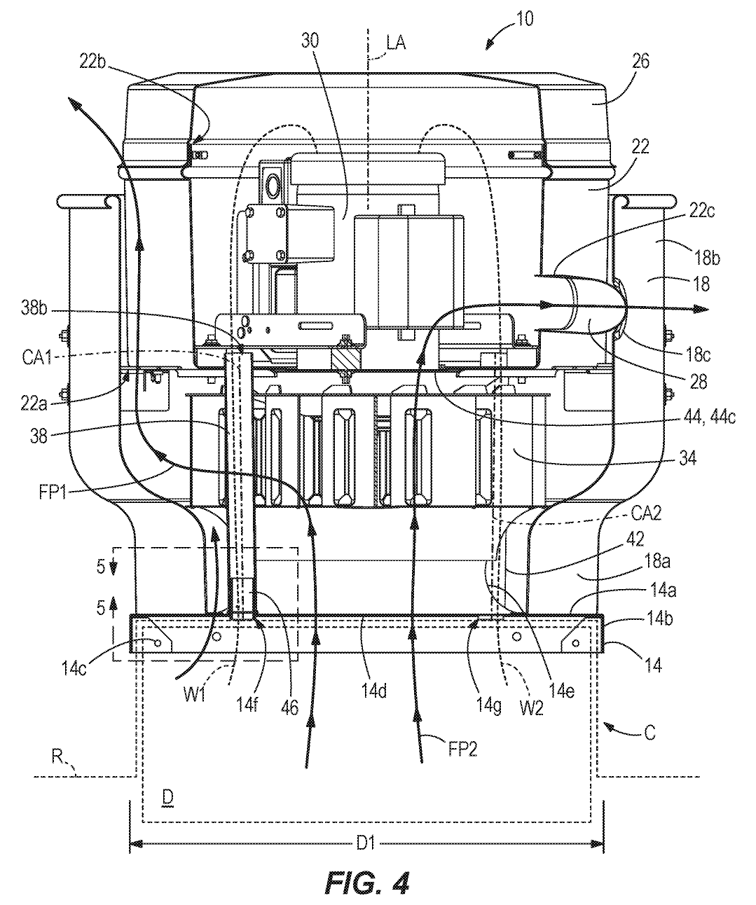

FIGS. 1 and 4 illustrate a fan 10 configured to exhaust air from a room or space within a building. The illustrated fan 10 is an exhaust fan 10 which, when mounted to a roof R of the building, is generally directed with a longitudinal axis LA extending away from the roof R or normal thereto. In the illustrated embodiment, for example, the longitudinal axis LA extends perpendicularly away from the roof R. As will be described herein, the fan 10 is an exemplary exhaust fan 10 including features which may be present in other types of fans 10.

The illustrated exhaust fan 10 includes a curb cap 14 configured for engagement with or affixing to a roof curb C on the roof R and to connect the exhaust fan 10 to ductwork D servicing the building. The ductwork D is in fluid communication with a room and is configured to pass fluid (e.g., air) from the room to the exhaust fan 10. A windband 18 is coupled to the curb cab 14 and positioned within is a hoodband 22. The hoodband 22 has a first axial end 22a and an opposite second axial end 22b. The first axial end 22a is positioned closer to the curb cap 14 than the second axial end 22b. A hood 26 is removably coupled to the second axial end 22b to provide access to the interior of the hoodband 22.

The curb cap 14 has a planar surface 14a, a plurality of sidewalls 14b, a plurality of fastener interfaces 14c provided on the plurality of sidewalls 14b, an airflow opening 14d provided in the planar surface 14a (FIG. 4), and a Venturi portion 14e adjacent the airflow opening 14d. As best illustrated in FIG. 4, the fastener interfaces 14c are configured to receive fasteners (not shown) to secure the exhaust fan 10 to the curb C.

The Venturi portion 14e is a portion of the curb cap 14 which extends in a direction away from the planar surface 14a oppositely from the sidewalls 14b. The Venturi portion 14e varies in cross-sectional size (e.g., diameter) in a direction generally parallel to the longitudinal axis LA. More specifically, the cross-sectional size (e.g., diameter) of the Venturi portion 14e is largest adjacent the planar surface 14a and the airflow opening 14d and is smallest at a distal end thereof spaced from the planar surface 14a. Fluid passing through the exhaust opening 14d is passed through the Venturi portion 14e with the Venturi portion 14e being configured to guide the exhaust airflow and to speed up the exhaust airflow as the exhaust airflow passes through the airflow opening 14d and subsequently the Venturi portion 14e. The downstream end (e.g., top end as viewed in FIG. 4) of the Venturi portion 14e is open to the interior of the windband 18.

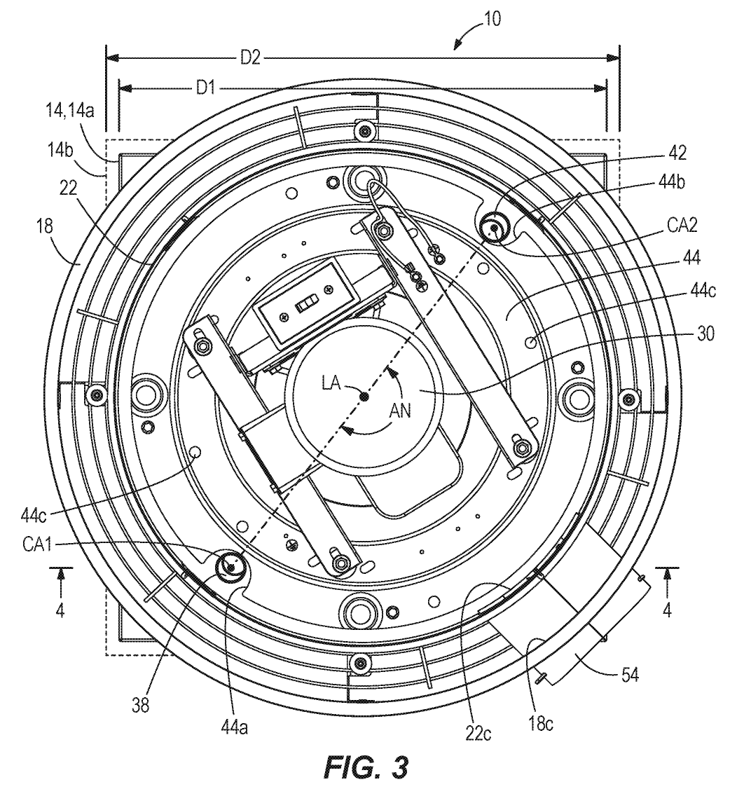

As illustrated in FIGS. 3 and 4, the curb cap 14 may be sized (e.g., dimensioned) to interface any curb C. Dimension D1 represents a first size of the curb cap 14 and is measured between opposing sidewalls 14b thereof. The illustrated curb cap 14 is shaped as a square, with dimension D1 therefore representing a side length thereof. Dimension D2 represents a second size of the curb cap 14, which is larger than the dimension D1. During manufacturing of the exhaust fan 10, the curb cap 14 may be formed with dimension D1 or dimension D2 depending on the size and dimensions of the corresponding curb C. Any number and sizes of dimensions D1, D2 (e.g., further dimensions D3, D4, D5 [not illustrated], etc.) are possible.

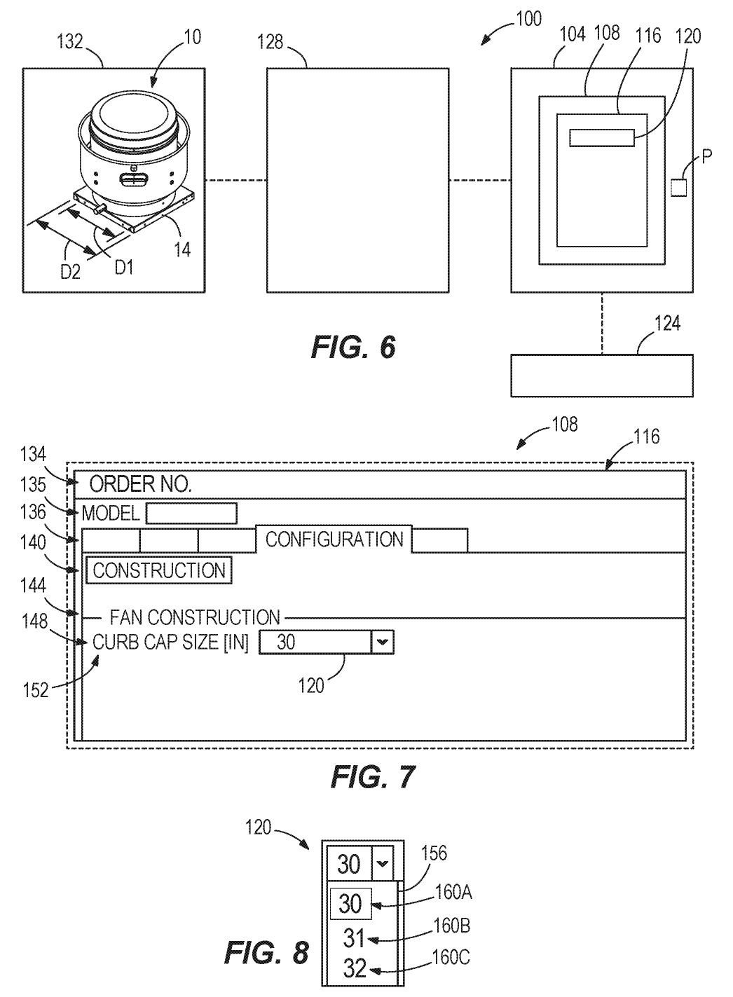

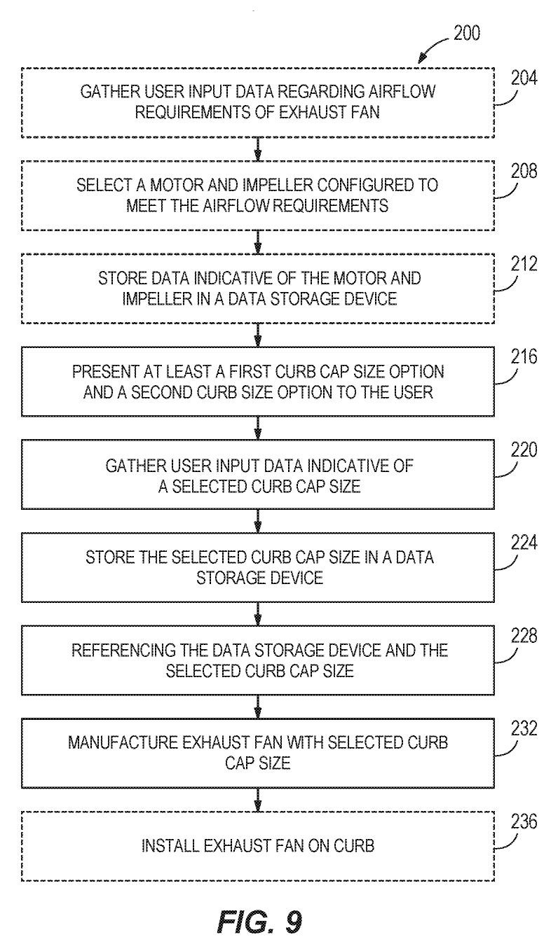

In the illustrated embodiment, a cross-sectional shape of the curb cap 14 in a direction perpendicular to the longitudinal axis LA, as represented by the sidewalls 14b, is square. The dimensions D1, D2 (D3, D4 . . . ) represent differing lengths of each side of the curb cap (e.g., sidewalls 14b) in separate embodiments of the curb cap 14, and more particularly differing lengths of the same corresponding side of those separate curb cap embodiments. In other embodiments, however, the curb cap 14 may have a different (e.g., circular, rectangular, elliptical, etc.) cross-sectional shape. The dimensions D1, D2 may then correlate to different dimensions of the corresponding cross-sectional shape (e.g., a diameter of the circle, a diagonal or length of the rectangle, etc.) such that D1, D2 are more generally representative of a primary geometric parameter of that cross-sectional shape, and can so be defined. As will be described in detail below with regard to FIGS. 6-9, the dimensions D1, D2 of the curb cap 14 are selectable by a user (e.g., end user, customer, person ordering the exhaust fan 10) during a curb cap size selection process 216-224 (FIG. 9) prior to manufacturing of the exhaust fan 10 to correspond with the corresponding curb C.

The windband 18 has a reduced size (e.g., diameter) portion 18a coupled to the curb cap 14 and an enlarged size (e.g., diameter) portion 18b extending from the reduced size portion 18a. The enlarged size portion 18b includes a vent hole 18c, and the hoodband 22 includes a vent hole 22c. A breather tube 28 provides fluid communication from the interior of the hoodband 22 to the exterior of the windband 18. The breather tube 28 is located between the vent hole 18c of the windband 18 and the vent hole 22c of the hoodband 22.

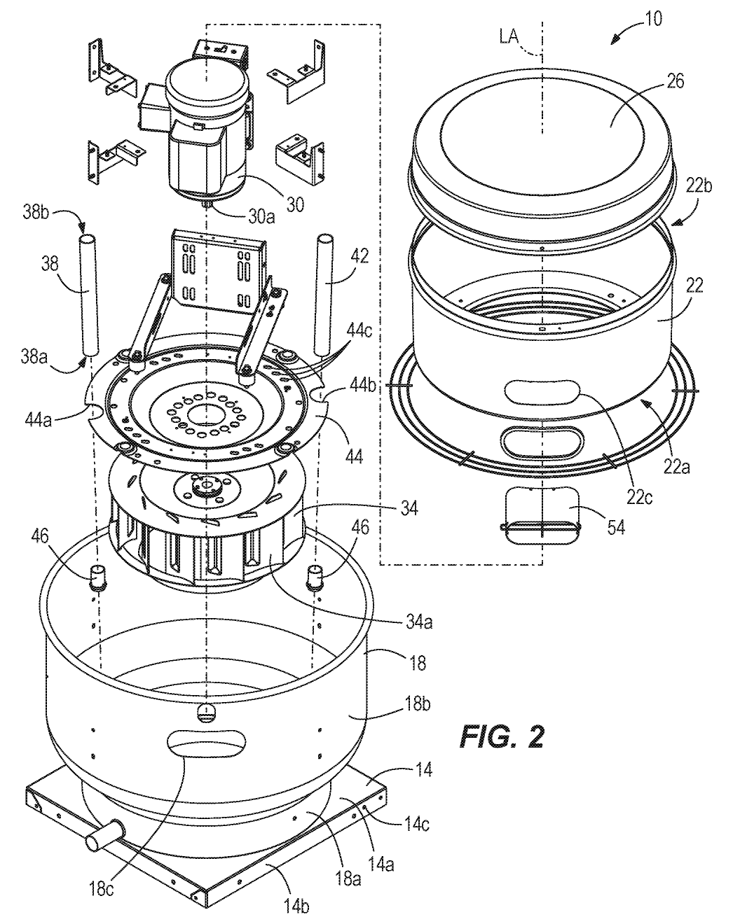

Referring to FIG. 2, the exhaust fan 10 further includes a motor 30 and an impeller 34 rotatably coupled to the motor 30 and operably configured to generate exhaust fluid flow. In the illustrated embodiment, the impeller 34 is positioned to rotate about the longitudinal axis LA. The impeller 34 may be a squirrel cage type impeller with a plurality of blades 34a each having a chord extending in a direction away from the longitudinal axis LA. The blades 34a of the illustrated impeller 34 are extruded along a height extending parallel to the longitudinal axis LA. In yet other embodiments, the impeller 34 may be of a different type or the impeller 34 may be differently oriented and rotate about a differing rotational axis (not shown) not necessarily concurrent or even parallel with the longitudinal axis LA of the exhaust fan 10. In yet other embodiments, the blades 34a may be otherwise oriented relative to the longitudinal axis LA. The illustrated motor 30 has a shaft 30a rotatably oriented coincident with the longitudinal axis LA. In other embodiments, the motor 30 may be differently oriented with respect to the longitudinal axis LA. In the illustrated embodiment, the shaft 30a is coupled to the impeller 34 such that operation of the motor 30 and subsequent rotation of the shaft 30a causes rotation of the impeller 34. In other embodiments, the motor 30 may be otherwise coupled to the impeller 34. For example, any type of drive system (e.g., transmission, gearbox, belt drive, etc.) may be coupled with and/or replace the shaft 30a for transmitting force (e.g., torque) from the motor 30 to the impeller 34. Various orientations, configurations, gear ratios, etc. of such a drive system are possible. As shown in FIGS. 2-4, the hoodband 22 circumscribes the motor 30 and the impeller 34. The windband 18 circumscribes the hoodband 22 and is radially spaced therefrom.

As illustrated in FIGS. 3-5, the curb cap 14 further includes a first conduit opening 14f and a second conduit opening 14g (FIG. 4) similar to the first conduit opening 14f. The conduit openings 14f, 14g are formed as holes in the planar surface 14a of the curb cap 14. The first conduit opening 14f and the second conduit opening 14g (FIG. 4) are distinct from one another and are also each distinct from the airflow opening 14d. The exhaust fan 10 further includes a first conduit 38 and a second conduit 42. The first conduit opening 14f generally corresponds with the first conduit 38, and the second conduit opening 14g generally corresponds with the second conduit 42. The conduit 38, 42 in an exemplary embodiment is made of an electrically insulative material. In some embodiments, for example, the conduit 38, 42 may be an electrically insulative plastic. Other types of conduit 38, 42 are possible, however, to include metallic conduits or other materials, which still serve an insulating or isolative function. In other embodiments, one or more layers of the conduit 38, 42 are electrically insulative. The conduit 38, 42 may be fire rated (e.g., flame retardant) to inhibit fire generation.

The exhaust fan 10 further includes a support pan 44, which supports the motor 30 thereon. The support pan 44 of the illustrated embodiment is generally oriented perpendicularly from the longitudinal axis LA. The support pan 44 is positioned within the hoodband 22 and is shaped as an annular disk. The support pan 44 is further coupled to the hoodband 22 and the windband 18. More specifically, the first axial end 22a of the hoodband 22 is removably coupled to and supported by the support pan 44. In the illustrated embodiment, the support pan 44 is supported by the enlarged size (e.g., diameter) portion 18b of the windband 18. The support pan 44 includes a first pan conduit opening 44a and a second pan conduit opening 44b. In the illustrated embodiment (FIG. 3), each of the pan conduit openings 44a, 44b are positioned at a periphery of the support pan 44, and each of the pan conduit openings 44a, 44b are shaped as semi-circular cutouts of the support pan 44. The support pan 44 further includes a plurality of airflow holes 44c. The conduits 38, 42 each extend at least between the pan conduit openings 44a, 44b of the support pan 44 and the conduit openings 14f, 14g of the curb cap 14. The pan conduit openings 44a, 44b are each aligned with the conduit 38, 42. In the illustrated embodiment (FIG. 4), the conduit 38 includes a first axial end 38a adjacent the curb cap 14. The conduit 38 further includes an opposite second axial end 38b located on an opposite side of the support pan 44 as the first axial end 38a. In other words, the conduits 38, 42 each pass entirely through the support pan 44 via the pan conduit openings 44a, 44b.

The conduits 38, 42 are in fluid communication with both the ductwork D and an interior volume V1 of the hoodband 22. As shown in FIG. 4, the volume V1 of the hoodband 22 extends axially along the longitudinal axis LA between the hood 26 and the support pan 44. The volume V1 extends radially between the longitudinal axis LA to the inner surfaces (e.g., sidewall) of the hoodband 22 and the hood 26. The first end 38a of the conduit 38 is in fluid communication with (e.g., open to) the ductwork D via the curb cap 14. The first axial end 38a of the conduit 38 is positioned within the windband 18 radially between the windband 18 and the longitudinal axis LA. The second axial end 38b of the conduit 38 is in fluid communication with the interior volume V1 of the hoodband 22. The second axial end 38b of the conduit 38 is positioned within the hoodband 22 radially between the hoodband 22 and the longitudinal axis LA. In the illustrated embodiment, the second axial end 38b of the conduit 38 is above the support pan 44 and within the interior volume V1 of the hoodband 22 in an axial direction along the longitudinal axis LA (FIGS. 3, 4). The conduit 38 traverses the support pan 44 to be exposed to the interior of the hoodband 22. In the illustrated embodiment of FIG. 4, the conduit 38 passes axially through the support pan 44. In other embodiments, the conduit 38 may traverse any combination of the windband 18 (e.g., the enlarged size portion 18b, the reduced size portion 18a, or a transition region between the enlarged size portion 18b and the reduced size portion 18a), the support pan 44, and the hoodband 22 (e.g., a sidewall thereof). For example, in some embodiments (not shown), the conduit 38 may extend in an axial direction from the curb cap 14 to a height corresponding with the motor 30 (e.g., at the enlarged size portion 18b of the windband 18), and the conduit 38 may be connected to a connector or otherwise angled (e.g., by a right angle connector) to communicate with the interior volume V1 of the hoodband 22 (e.g., via a sidewall of the hoodband 22), with the conduit 38 or the connector extending in a radially inward direction toward the longitudinal axis LA.

The windband 18 defines a volume V2 axially below (e.g., facing the curb cap 14) a distal end of the enlarged size portion 18b and above the curb cap 14. At an axial position corresponding with the position of the hoodband 22, the volume V2 is further defined in a radial direction between the outer surface of the hoodband 22 and the inner surface of the windband 18. Axially below the hoodband 22, the volume V2 is defined in a radial direction between the inner surface of the windband 18 and the longitudinal axis LA. The conduits 38, 42 are in communication with the ductwork D and the volume V1, and the conduits 38, 42 generally pass through the volume V2.

FIG. 3 illustrates a top view of the exhaust fan 10 with the hood 26 removed to show the interior of the exhaust fan 10. The conduit 38 extends along a conduit axis CA1, and the conduit 42 extends along a conduit axis CA2. The conduit 38, 42, is rigid and is shaped as a hollow linear extrusion (e.g., a hollow cylinder, an annular cylinder) in the illustrated embodiment. The conduit axes CA1, CA2 in the illustrated embodiment are parallel with the longitudinal axis. In some embodiments, the conduit axes CA1, CA2, may extend in non-parallel directions relative to the longitudinal axis LA, for example, angled with respect to the longitudinal axis LA (e.g., by between 0 and 90 degrees, more specifically, between 1 and 10 degrees) and in any direction, i.e., clockwise, relative thereto. For example, the conduit axes CA1, CA2, or segmented conduit axes CA1, CA2 themselves defined by segmented portions of the conduits 38, 42, (e.g., segmented linear portions of conduits 38, 42) may intersect, but be angled (e.g., any amount between 0 and 90 degrees, such as 30 degrees, 45 degrees, 60 degrees, etc.) towards or away from the longitudinal axis LA. In other embodiments still, the conduit axes CA1, CA2, or segmented conduit axes CA1, CA2 themselves defined by segmented portions of differing conduits 38, 42 (e.g., segmented linear portions of conduits 38, 42) may be angled in a tangential manner, a partially tangential manner, a helical or helical-type manner, or the like, with the conduits 38, 42 extending generally circumferentially around the longitudinal axis LA as the conduits 38, 42 pass between the curb cap 14 and into the hoodband 22. As illustrated in FIG. 4, the conduit 38 is slightly (e.g., approximately 2 degrees) angled relative to the longitudinal axis LA, and each of conduit 38 and conduit 42 may be differently directed or angled to the axis LA and to the other of conduit 38, 42. In other embodiments, the conduit 38, 42 may be flexible, non-linearly shaped, or cylindrically shaped with one or more differing cross-sectional shapes other than annuluses.

The conduits 38, 42 are in fluid communication with both the ductwork D and an interior volume V1 of the hoodband 22. As shown in FIG. 4, the volume V1 of the hoodband 22 extends axially along the longitudinal axis LA between the hood 26 and the support pan 44. The volume V1 extends radially between the longitudinal axis LA to the inner surfaces (e.g., sidewall) of the hoodband 22 and the hood 26. The first end 38a of the conduit 38 is in fluid communication with (e.g., open to) the ductwork D via the curb cap 14. The first axial end 38a of the conduit 38 is positioned within the windband 18 radially between the windband 18 and the longitudinal axis LA. The second axial end 38b of the conduit 38 is in fluid communication with the interior volume V1 of the hoodband 22. The second axial end 38b of the conduit 38 is positioned within the hoodband 22 radially between the hoodband 22 and the longitudinal axis LA. In the illustrated embodiment, the second axial end 38b of the conduit 38 is above the support pan 44 and within the interior volume V1 of the hoodband 22 in an axial direction along the longitudinal axis LA (FIGS. 3, 4). The conduit 38 traverses the support pan 44 to be exposed to the interior of the hoodband 22. In the illustrated embodiment of FIG. 4, the conduit 38 passes axially through the support pan 44. In other embodiments, the conduit 38 may traverse any combination of the windband 18 (e.g., the enlarged size portion 18b, the reduced size portion 18a, or a transition region between the enlarged size portion 18b and the reduced size portion 18a), the support pan 44, and the hoodband 22 (e.g., a sidewall thereof). For example, in some embodiments (not shown), the conduit 38 may extend in an axial direction from the curb cap 14 to a height corresponding with the motor 30 (e.g., at the enlarged size portion 18b of the windband 18), and the conduit 38 may be connected to a connector or otherwise angled (e.g., by a right angle connector) to communicate with the interior volume V1 of the hoodband 22 (e.g., via a sidewall of the hoodband 22), with the conduit 38 or the connector extending in a radially inward direction toward the longitudinal axis LA.

The windband 18 defines a volume V2 axially below (e.g., facing the curb cap 14) a distal end of the enlarged size portion 18b and above the curb cap 14. At an axial position corresponding with the position of the hoodband 22, the volume V2 is further defined in a radial direction between the outer surface of the hoodband 22 and the inner surface of the windband 18. Axially below the hoodband 22, the volume V2 is defined in a radial direction between the inner surface of the windband 18 and the longitudinal axis LA. The conduits 38, 42 are in communication with the ductwork D and the volume V1, and the conduits 38, 42 generally pass through the volume V2.

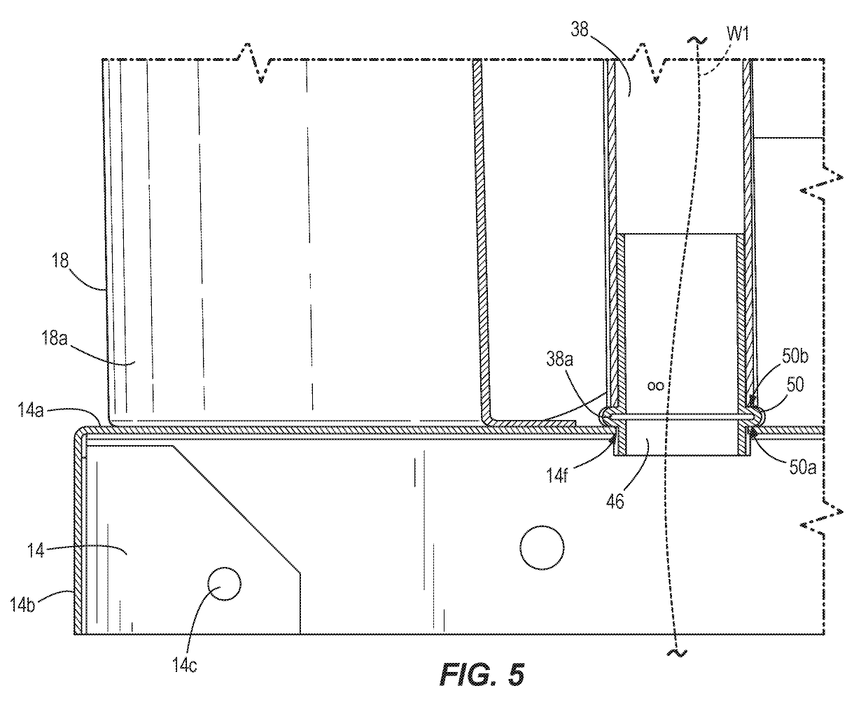

As shown in FIGS. 4 and 5, the exhaust fan 10 includes a connector 46 positioned adjacent the first axial end 38a between the curb cap 14 and the conduit 38. The connector 46 couples the conduit 38 to the curb cap 14. The connector 46 includes a lip 50 which is larger in size than the first conduit opening 14f. The lip 50 projects outwardly from the remainder of the connector 46. The connector 46 is press-fit into the first conduit opening 14f, and the conduit 38 is press-fit onto the connector 46. The lip 50 has a curb cap facing-side 50a (i.e., a first side) which presses against the planar surface 14a of the curb cap 14 once the connector 46 is secured to the curb cap 14. The lip 50 further includes a conduit facing-side 50b, which the first axial end 38a of the conduit 38 presses against once the conduit 38 is secured to the connector 46. As would be appreciated by one of ordinary skill in the art, inner and outer diameters of the first conduit opening 14f, connector 46, lip 50, and conduit 38 are selected to permit press-fit coupling between the curb cap 14, the connector 46, and the conduit 38. Another similar connector 46 may secure the conduit 42 to the second conduit opening 14g. With reference to FIGS. 3 and 4, the second axial end 38b of the conduit 38 is passed through the first pan conduit opening 44a. The first pan conduit opening 44a and the conduit 38 are dimensioned such that the support pan 44 inhibits deflection of the conduit 38 in directions non-parallel with the longitudinal axis LA. As the illustrated connectors 46 are configured to interface with both the conduit openings 14f, 14g and the conduits 38, 42 in press-fit relationships, any sequence of connection between the connectors 46, the conduits 38, 42, and the curb cap 14 is possible.

Wires W1, W2, which provide power current and/or control signals to the motor 30 are passed through the conduits 38, 42 from the curb cap 14 to the interior of the hoodband 22 for connection with the motor 30. The first wire W1 passes through the first conduit opening 14f, the first conduit 38, and the first pan conduit opening 44a. The second wire W2 passes through the second conduit opening 14g, the second conduit 42, and the second pan conduit opening 44b.

In operation, exhaust generated by the impeller 34 passes from the room or space within the building, through the ductwork D and the impeller 34, and to the surroundings of the exhaust fan 10 external to the roof R. The exhaust airflow generated by the impeller 34 passes along a first flow path FP1 and a second flow path FP2 (FIG. 4). The first flow path FP1 passes exhaust airflow through, in sequence, the airflow opening 14d, the impeller 34, and a space (e.g., the volume V1) between the windband 18 and the hoodband 22. The second flow path FP2 passes exhaust airflow through, in sequence, the airflow opening 14d (and optionally the conduit 38, 42), the airflow holes 44c of the support pan 44, the interior of the hoodband 22, and the breather tube 28 before being exhausted to the surroundings of the exhaust fan 10. The second flow path FP2 may provide cooling airflow for the motor 30. When coupled to the hoodband 22, the hood 26 redirects the second flow path FP2 towards the breather tube 28.

FIGS. 6-8 illustrate a system 100 for conducting the curb cap size selection process 216-224 and facilitating the subsequent manufacturing of the above-described exhaust fan 10. The system 100 provides means for a user to select the above-described dimension D1 (e.g., one of D1-D4) of the curb cap 14 to fit differently sized curbs C. As illustrated in FIG. 6, the system 100 includes a data collection device 104 having a display 108, a user input device 124, a data storage device 128, and an assembly subsystem 132. The components of the system 100 are in communication (e.g., mechanical, electrical communication) with one another in order to function as described herein. In some embodiments, the data collection device 104 may be operated by an end user of the exhaust fan 10 (e.g., a customer, end user, such as a facilities manager of a building) or a designer or other construction personnel, contractor, etc., in the curb cap size selection process 216-224 before the assembly subsystem 132 manufactures the exhaust fan 10 the curb cap 14 having the desired dimension D1 (e.g., one of D1-D4).

The data collection device 104, display 108, user-input device 124, and storage device 128 may be any type of device or any type of interconnected devices (e.g., a computer, mouse, cell-phone, etc.). In some embodiments, the data collection device 104 may be a computer connected to a monitor which functions as the display 108 and a mouse which functions as the user input device 124. In other embodiments, the data collection device 104 may be a tablet or cellular telephone device with an integrated touch screen which functions as the display 108 and the user input device 124. The data storage device 128 may be either integrated with the data collection device 104 (e.g., on-board computer or cell-phone storage) or an off-board (e.g., remote) storage device (e.g., a remote database, a remote server). The data storage device 128 is configured to store data in relation with the selected curb cap size (corresponding with any one of dimensions D1-D4) for future reference. The data storage device 128 is also configured to store data in relation to other features of the exhaust fan 10. For example, the data storage device 128 may store data relating to specifications (e.g., size, shape, capacity, orientation within the exhaust fan 10, etc.) of the motor 30 or impeller 34. Other arrangements or types of devices are possible.

At least one of the data collection device 104, user-input device 124, storage device 128, or the assembly subsystem 132 includes a processor P. The processor P is configured to facilitate intercommunication of the components of the system 100 for operation of the curb cap selection process 216-224. In the illustrated embodiment of FIG. 6, the processor P is an integrated component of the data collection device 104. However, the processor P may be a remote device, or be present on or within either or both of the storage device 128 and the assembly subsystem 132.

The display 108 of the data collection device 104 is configured to present a user with a first curb cap size option (corresponding with dimension D1) and a second curb cap size option (corresponding with dimension D2). As shown in FIGS. 6-8, the display 108 can provide visual display of a window 116 to a user. The window 116 includes a curb size dropdown menu 120. Optionally, the window 116 or another window 116 may present other options relating to the construction of the exhaust fan 10 to the user. For example, the window 116 may present options relating to size, performance, operating speed, volumetric flow rates, etc., in relation with the motor 30 and/or the impeller 34.

FIG. 7 illustrates an exemplary view of the display 108. The display 108 shows a graphical user interface including the window 116 to the user. The window 116 includes a top ribbon 134 configured to indicate to the user which order (e.g., order number) the window 116 currently relates to. The window 116 further includes a model field 135 configured to indicate to the user a model number of the exhaust fan 10. The first toolbar 136 includes a plurality of tabs. Each of the tabs of the first toolbar 136 may relate to different user input data for manufacturing the exhaust fan 10. Similarly, the illustrated window 116 includes a second toolbar 140 including a second plurality of tabs. In the illustrated embodiment, a “configuration” tab of the first toolbar 136 is selected, and a “construction” tab of the second toolbar 140 is selected. When the “configuration” and “construction” tabs are selected, the window 116 presents at least a fan construction module 144. In other embodiments, any combination of tabs, and optionally no tabs, may be selected to present the fan construction module 144 and the curb cap size dropdown menu 120.

The fan construction module 144 includes at least one fan construction option 148 and a fan construction indicator 152. The fan construction indicator 152 indicates to the user a corresponding element of the exhaust fan 10 to be adjusted by adjusting the fan construction option 148. In the illustrated embodiment, the fan construction indicator 152 states “Curb Cap Size (in.)” to indicate to the user that the fan construction option 148 relates to selecting the desired dimension D1 or dimension D2 of the curb cap 14, as well as the corresponding units (inches). The curb size dropdown menu 120 is positioned adjacent to the fan construction indicator 152. In the illustrated embodiment, the curb size dropdown menu 120 is automatically populated with a size (e.g., the dimension D1). This automatically populated dimension (e.g., D1) may correlate with a specified size of the curb cap in correspondence with the selected motor 30 (e.g., any characteristic such as RPM, power, etc. of the motor 30) and impeller 34 (e.g., any characteristic such as blade shape, number of blades, etc. of the impeller 34) (e.g., the model number in the model field 135). In the illustrated example, the data relating to the motor 30 and impeller 34 (e.g., a fan subassembly) has been previously input into the data collection device 104, and the data collection device 104 (e.g., a controller thereof) has determined that a suggested curb cap size (e.g., dimension D1) for the motor 30 and impeller 34 is 30 inches, and the suggested curb cap size (e.g., “30” [inches]) is displayed in the curb size dropdown menu 120.

The curb size dropdown menu 120 is further illustrated in an engaged (e.g., “selected”) status in FIG. 8. In the engaged status, the display 108 presents a curb size dropdown field 156. The curb size dropdown field 156 displays a plurality of curb cap size options 160A-160C. In the illustrated embodiment, the curb cap size option 160A represents the suggested curb cap size (e.g., dimension D1) of 30 inches. The curb cap size options 160B-160C represent oversized curb cap sizes (e.g., generally corresponding with dimension D2) of 31inches, and 32inches (e.g., dimension D3), respectively. The curb size dropdown field 156 may display any number of curb cap size options 160A-160C. For example, the curb size dropdown field 156 may display more than four curb cap size options 160A-160C.

While the curb cap size options 160A-160C present curb cap sizes between 30 and 32 inches, curb cap size options 160A-160C may be presented in variously spaced increments. The exemplary cap size options 160A-160C are provided in equally spaced one-inch increments from one another. In other examples, the exemplary cap size options 160A-160C may be provided in any equally spaced increment (e.g., quarter-inch, half-inch, three-quarter inch, two-inch, greater than two-inch etc. increment) from one another (e.g., 30, 30.5, 31, 31.5 inches) (e.g., 30, 30.25, 30.5, 30.75 inches). In other examples, different and/or unequal spacing between curb cap size options 160A-160C is possible (e.g., 30, 30.5, 32, 35 inches). In some embodiments, curb cap size options 160A-160C may be provided as whole number integers between 10 inches and 100 inches. In other embodiments, curb cap size options 160A-160C may be provided between 30 inches and 64 inches. In still other embodiments, a smallest curb cap size option 160A of a group of four or more curb cap options (e.g., 30, 31, 32, 34 inches, each being whole number integers) has a curb cap size equivalent to a suggested curb cap size (e.g., dimension D1) for the motor 30 and the impeller 34, and the remaining of the four or more curb caps 14 have oversized curb cap sizes (e.g., dimensions D2) greater than the suggested curb cap size (e.g., dimension D1). In other instances, more or less than four curb cap sizes (e.g., two curb cap sizes, three curb cap sizes, four curb cap sizes, more than four curb cap sizes dimensions D1) may be capable of being presented and selected. In some alternative embodiments, other curb cap size options (not shown) having undersized cap sizes (e.g., dimensions D5 [not shown], 29 inches) lesser than the suggested curb cap size (e.g., dimension D1) may be presented and capable of being selected.

The assembly subsystem 132 is configured to receive data from the data storage device 128 indicative of the selected curb cap size (e.g., corresponding with any one of the dimensions D1-D4), and the assembly subsystem 132 is further configured to manufacture the exhaust fan 10 with the selected curb cap size (e.g., with dimension D1). In some embodiments, the assembly subsystem 132 may be operated by human assemblers. In some embodiments, the assembly subsystem 132 may be operated at least in part by automated (e.g., robotic) assembling machines (not shown).

FIG. 9 illustrates a method 200 including the curb cap size selection process 216-224 as well as manufacturing and installation of the exhaust fan 10. The method 200 is a computer-implemented method conducted at least in part by the aforementioned processor P.

At step 204, user input data regarding airflow requirements of the exhaust fan 10 is gathered. At step 208, a motor 30 and impeller 34 are selected to meet the airflow requirements of the exhaust fan 10. At step 212, data indicative of the selected motor 30 (e.g., a motor characteristic, RPM, power, etc.) and impeller 34 (e.g., an impeller characteristic, blade shape, number of blades, etc.) is stored in the data storage device 128. The dashed lines for steps 204, 208, 212 represent optional steps not required for the curb size selection portion of the method 200.

Steps 216-224 generally represent the curb size selection process 216-224 of the method 200. At step 216, (in the illustrated embodiment, upon interaction with the dropdown menu 120) a first curb cap size option 160A and a second curb cap size option 160B are presented to the user via the display 108. The first curb cap size option 160A and second curb cap size option 160B are displayed upon selection (e.g., engagement) of the display dropdown menu 120 by the user. If desired to modify the dimension D1 (e.g., any one of D1-D4) of the curb cap 14 from suggested curb cap size (e.g., based on the motor 30 and impeller 34, dimension D1, 30 inches in FIG. 7) to a different curb cap size (e.g., to dimension D2, 31 inches), the user input device 124 is operated to select the display dropdown menu 120. Upon selection of the display dropdown menu 120, the display 108 expands the curb cap size dropdown menu 120 to show the curb size dropdown field 156 and any number of curb cap size options 160A-160C.

At step 220, the data collection device 104 gathers further user input data from the user via the user input device 124, the data being indicative of a selected curb cap size (e.g., dimension D2, 31 inches). For example, the user may select (e.g., by clicking or tapping on, interacting with) a desired curb cap size (e.g., dimension D2, 31 inches) for the exhaust fan 10 different than the suggested curb cap size (e.g., dimension D1, 30 inches). During step 220, the user input device 124 is monitored by the processor P to determine which of curb cap size options 160A-160C is selected by the user via the user input device 124 (e.g., upon action of the user to select the first curb cap size or the second curb cap size).

At step 224, the selected curb cap size is communicated from the user input device 104 to the data storage device 128 (e.g., via the processor P) for storage in the data storage device 128. The curb size selection process 216-224 is complete upon storing the data relating to the selected curb cap size in the data storage device 128.

Steps 228-232 relate to subsequent manufacturing and installation of the exhaust fan 10 after the curb size selection process 216-224. At step 228, the assembly subsystem 132 references the data storage device 128 and the selected curb cap size (e.g., dimension D2). At step 232, the assembly subsystem 132 manufactures the exhaust fan 10 with the selected curb cap size (e.g., dimension D2). At step 236, the exhaust fan 10 is installed on the roof curb C.

The curb cap size selection process 216-224 described above and illustrated in the figures relate to an exhaust fan 10 which may be referred to as a roof-mounted upblast exhaust fan 10 mounted to the curb C of the roof R. The above-described features of the exhaust fan 10 and the curb cap size selection process 216-224 may be applied equally to other types of fans 10 other than roof-mounted upblast exhaust fans 10. For example, the aforementioned fan 10 may be in the form of a sidewall fan mounted on a sidewall or a downblast fan. Either type of fan 10 (e.g., roof-mounted, sidewall-mounted, underhang or downwardly mounted) may be configured as either an exhaust fan (which exhausts air from the ducts D to the surroundings of the fan 10) or a supply fan (which supplies outside air into the associated ducts D). In any case, the features described above with regard to the conduit 38, 42 and curb cap size selection process 216, 224, of the aforementioned exhaust fan 10 may be present in various forms with any type or combination of supply, exhaust, roof-mounted, sidewall-mounted, downward-mounted or downblast, or other such fan.

The embodiment(s) described above and illustrated in the figures are presented by way of example only and are not intended as a limitation upon the concepts and principles of the present disclosure. As such, it will be appreciated that variations and modifications to the elements and their configuration and/or arrangement exist within the spirit and scope of one or more independent aspects as described.

Various features of the disclosure are set forth in the following claims.

What is claimed is:

1. A system for manufacturing a fan with a curb cap having a sidewall for coupling to a roof curb, the system comprising:
a data collection device having a display configured to present
a first curb cap option defining a first curb cap sidewall dimension configured to interface with a first roof curb,
a second curb cap option defining a second curb cap sidewall dimension configured to interface with a second roof curb, and
a third curb cap option defining a third curb cap sidewall dimension configured to interface with a third roof curb,
wherein the first curb cap sidewall dimension, the second curb cap sidewall dimension, and the third curb cap sidewall dimension are numerically different from one another, and
wherein the first roof curb, the second roof curb, and the third roof curb are different from one another;
a user input device in communication with the data collection device, the user input device operable by a user to select either the first curb cap option, the second curb cap option, or the third curb cap option;
a data storage device configured to store data relating to the selected curb cap option; and
an assembly subsystem configured to receive the data from the data storage device and at least partially manufacture the fan with the curb cap having a sidewall at least partially defining the sidewall dimension of the selected curb cap option.

2. The system of claim 1, wherein the sidewall is couplable to the roof curb via a fastener with the sidewall contacting the roof curb.

3. The system of claim 1, wherein
the first curb cap sidewall dimension and the second curb cap sidewall dimension are separated by a first numerical increment;
the second curb cap sidewall dimension and the third curb cap sidewall dimension are separated by a second numerical increment; and
the first numerical increment and the second numerical increment are equal.

4. The system of claim 3, wherein the first numerical increment and the second numerical increment are each a fraction of an inch.

5. The system of claim 3, wherein the first numerical increment and the second numerical increment are each whole number integers of at least one inch and the first curb cap sidewall dimension, the second curb cap sidewall dimension, and the third curb cap sidewall dimension are provided as whole number integers equal to or between 10 inches and 100 inches.

6. The system of claim 1, wherein
the first curb cap option further defines a fourth curb cap sidewall dimension;
the second curb cap option further defines a fifth curb cap sidewall dimension; and
the third curb cap option further defines a sixth curb cap sidewall dimension.

7. The system of claim 1, wherein the sidewall is one of a plurality of four sidewalls, the four sidewalls collectively forming a square, and the sidewall dimension being a side length between opposite sidewalls of the square.

8. A method of manufacturing a fan with a curb cap having sidewalls configured to interface with a roof curb, the method comprising:
gathering user input data regarding airflow requirements of the fan;
selecting a motor and an impeller configured to meet the airflow requirements;
storing data regarding the selected motor and the selected impeller in a data storage device;
presenting to a user
a first curb cap option defining a first curb cap sidewall dimension configured to interface with a first roof curb,
a second curb cap option defining a second curb cap sidewall dimension configured to interface with a second roof curb, and
a third curb cap option defining a third curb cap sidewall dimension configured to interface with a third roof curb;
gathering user input data regarding a user selected curb cap representing either the first curb cap option, the second curb cap option, or the third curb cap option; and
at least partially manufacturing with an assembly subsystem the fan with the motor, the impeller, and the curb cap having a sidewall with the sidewall dimension of the selected curb cap option.

9. The method of claim 8, further comprising providing the sidewall with a plurality of fastener interfaces for securing the curb cap to the roof curb with the sidewall contacting the roof curb.

10. The method of claim 8, wherein the first curb cap sidewall dimension and the second curb cap sidewall dimension are separated by a numerical increment and the second curb cap sidewall dimension and the third curb cap sidewall dimension are separated by the numerical increment.

11. The method of claim 10, wherein the numerical increment is a fraction of an inch.

12. The method of claim 10, wherein the numerical increment is a whole number integer such that the first curb cap sidewall dimension, the second curb cap sidewall dimension, and the third curb cap sidewall dimension are provided as whole number integers between 10 inches and 100 inches.

13. The method of claim 8, wherein the curb cap is manufactured having sidewalls collectively forming a square-shaped cross-section, each sidewall having the sidewall dimension.

14. A fan comprising:
a motor, and
an impeller rotatably coupled to the motor,
wherein the motor is configured to be coupled to any one curb cap selected from a group of three or more curb caps, each of the curb caps of the group having a curb cap sidewall dimension differing from the curb cap sidewall dimension of the other curb caps of the group by a predetermined numerical increment.

15. The fan of claim 14, wherein each of the curb caps of the three or more curb caps comprise a sidewall with a fastener interface for coupling of the any one curb cap to a roof curb with the sidewall contacting the roof curb.

16. The fan of claim 14, wherein the predetermined numerical increment is a fraction of an inch.

17. The fan of claim 14, wherein the predetermined numerical increment is a whole number integer of at least one inch.

18. The fan of claim 14, wherein each of the curb caps of the three or more curb caps has a plurality of sidewalls, the curb cap sidewall dimension being measured between at least two sidewalls and being numerically between 10 inches and 100 inches.

19. The fan of claim 18, wherein each of the curb caps of the three or more curb caps the curb cap sidewall dimension being numerically between 30 inches and 64 inches.

20. The fan of claim 14, wherein at least one curb cap selected from a group of three or more curb caps includes a plurality of four sidewalls, the four sidewalls collectively forming a square, and the sidewall dimension being a side length between opposing sidewalls of the square.
